(19) United States
(12) Patent Application Publication
(10) Pub. No.: US 2005/0042777 A1
(43) Pub. Date: Feb. 24, 2005

(54) Control of etch and deposition processes

(75) Inventors: Michael Stephen Boger, San Jose, CA (US); Mark Holbrook, Ayrshire (GB); David Heason, Glasgow (GB); Florian L'Hostis, Otago (NZ); David Reeve, Queensland (AU)

Correspondence Address: DAVID S. RESNICK;NIXON PEABODY LLP, 100 SUMMER STREET, BOSTON, MA, 02110, US

(73) Assignee: The BOC Group Inc., Murray Hill, NJ (US)

(21) Appl. No.: 10/644,274

(22) Filed: Aug. 20, 2003

(51) Int. Cl. H01L 21/76; H01L 21/00; H01L 21/66; G01R 31/26; H01L 21/302; H01L 21/461

(52) U.S. Cl. 438/8; 438/16

(57) ABSTRACT

This invention relates to the control of etch and deposition processes in the manufacture of semiconductor devices, microelectronic machines (MEMs), and waveguides.

### FIELD OF THE INVENTION

This invention relates to the control of etch and deposition processes in the manufacture of semiconductor devices, microelectronic machines (MEMs), and waveguides.

### BACKGROUND TO THE INVENTION

It is well known that interferometric techniques can be applied to determining the endpoint in thin film deposition or etch. However, these techniques have been limited in their application to feature sizes of a few microns or greater, since the probe light is incapable of resolving smaller structures due to the diffraction limit of the probe light. Contemporary feature structures are becoming so small that they are less than the diffraction limit in dimension and the prior art techniques are becoming less useful and applicable because of this limit.

An object of the present invention is accordingly to provide a method of monitoring semiconductor processes such as etch and deposition involving small feature sizes. Desirable and achievable outcomes of proper use of these techniques are elimination of the etch stop layer in dielectric etch, an improvement in control of shallow trench isolation etch, an improvement in gate oxide etch, an improvement in gate etch, an improvement in trench etch for memory applications, and an improvement in gate spacer etch. The invention is also applicable to the control of a range of micro-machining applications.

### BRIEF DESCRIPTIONS OF THE INVENTION

The invention provides a method for improved control of etch or deposition in a semiconductor manufacturing process to produce a structure having a small feature size.

A spectrally narrow illumination source is provided at a selected wavelength or wavelengths, from which an optical probe measurement beam is generated.

An article undergoing processing is illuminated with said beam, the article having within the area of illumination an ordered feature arrangement having a feature size of the same order as the structure of the device to be fabricated and being arranged in a regular pattern the pattern exhibiting a given feature spacing or a given set of feature spacings.

Where the illumination source provides a beam normal to the surface of the article being processed, each said wavelength within the measurement probe beam is chosen such that a whole number of wavelengths compounds to a length equal to within +/−30% of one of the feature spacings.

Where the illumination source provides a beam that is not normal to the surface of the article being processed, each wavelength within the measurement probe beam is selected such that a whole number of wavelengths compounds to a length equivalent to within +/−30′ of the projection of one of the feature spacings on a plane normal to the measurement probe beam.

An oscillation of a polarisation component in the light beam reflected from the article being processed is detected as the etch or deposition progresses, which oscillation is derived substantially from anomalous reflection or Rayleigh resonance at the feature arrangement resulting from the illumination. The oscillation is used to detect or predict the desired endpoint or monitor the progress in real time of the etch or deposition.

The ordered feature arrangement may be a test structure applied to the article for the purpose of monitoring the process, or may comprise structural features of the desired article itself.

Any overlying mask is preferably substantially opaque to the wavelength of the illumination source, and preferably the ordered feature arrangement has a ratio of feature open to etch to features masked from the etch of between 5% and 95%.

From another aspect, the present invention provides apparatus for use in a semiconductor manufacturing process, the apparatus comprising:
a vacuum enclosure;
a workpiece location within the enclosure for locating a semiconductor workpiece to be processed to produce a structure having a small feature size, said semiconductor workpiece having an ordered feature arrangement having a feature size of the same order as the structure to be produced and being arranged in a regular pattern having a given feature spacing or a set of feature spacings;
a spectrally narrow illumination source producing light at one or more wavelengths within 30% of a whole number of wavelengths of a size equal to the projection on a plane normal to the illumination beam of said feature spacing or feature spacings;
optical projection means cooperating with the light source to produce an optical probe measurement beam directed to said workpiece location;
optical detection means arranged to detect an oscillation of a polarisation component in the light beam reflected from the article being processed which is derived substantially from anomalous reflection or Rayleigh Resonance at the feature arrangement resulting from the illumination; and
data processing means arranged to use the oscillation to detect or predict the desired endpoint or monitor the progress in real time of the etch or deposition.

Other preferred features and advantages of the invention will be apparent from the following description and the claims.

### DETAILED DESCRIPTION OF THE INVENTION

An embodiment of the invention will now be described, by way of example only, with reference to the drawings, in which:

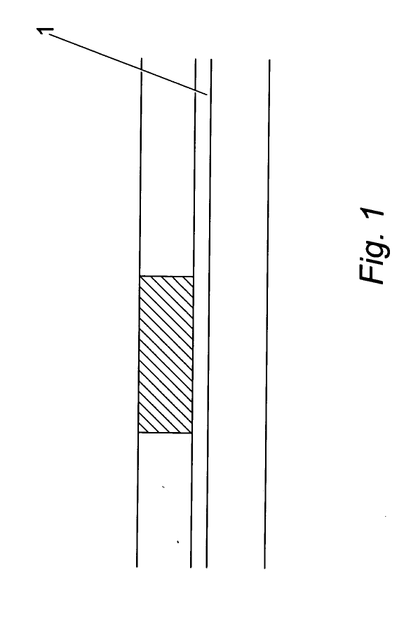

FIG. 1 is a cross-section of a typical prior art semiconductor construction;

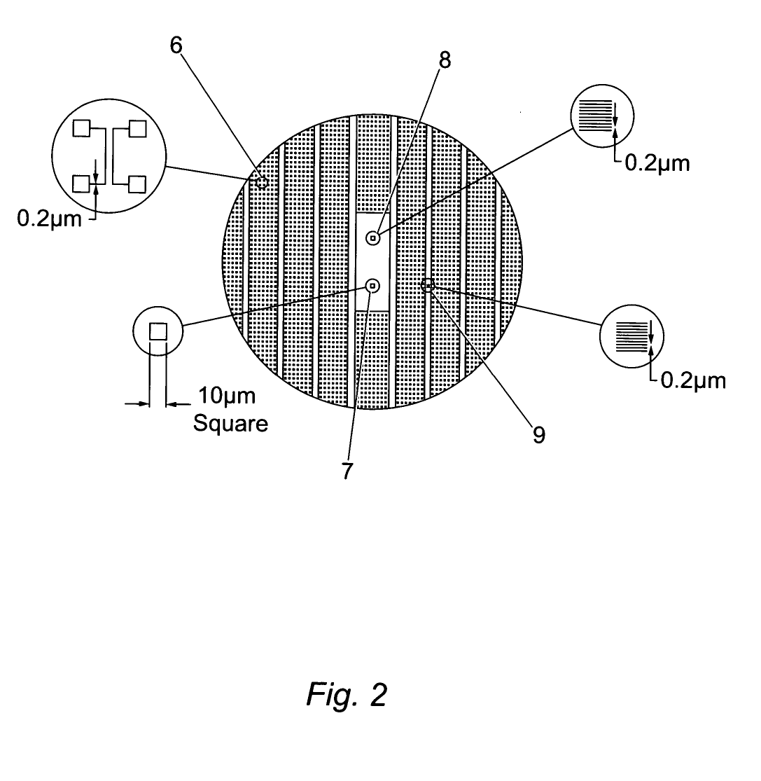

FIG. 2 is a front view of a silicon wafer showing structures used in the method of the invention;

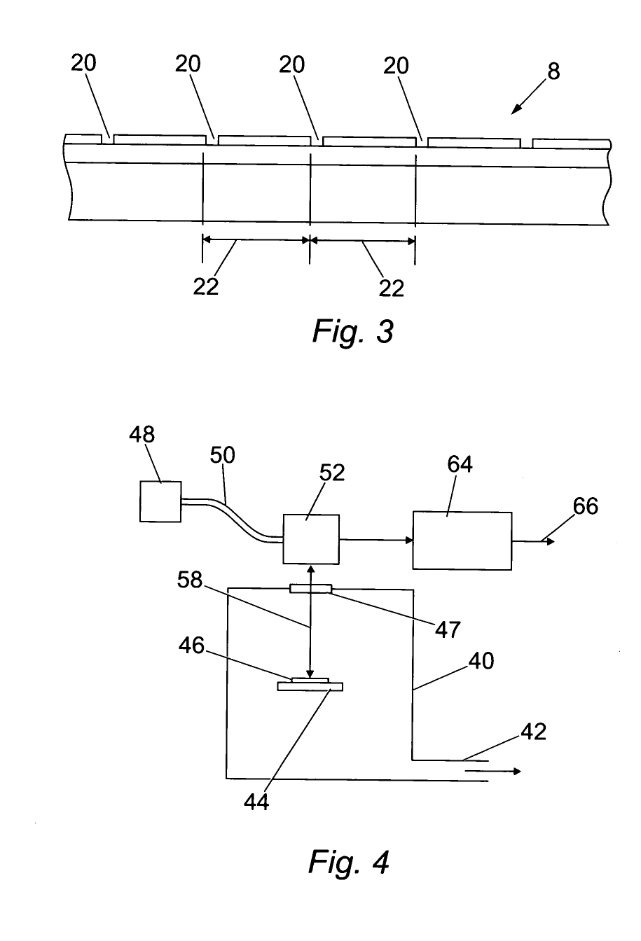

FIG. 3 is a cross-section of part of FIG. 2 to an enlarged scale;

FIG. 4 is a schematic of an apparatus embodying the invention; and

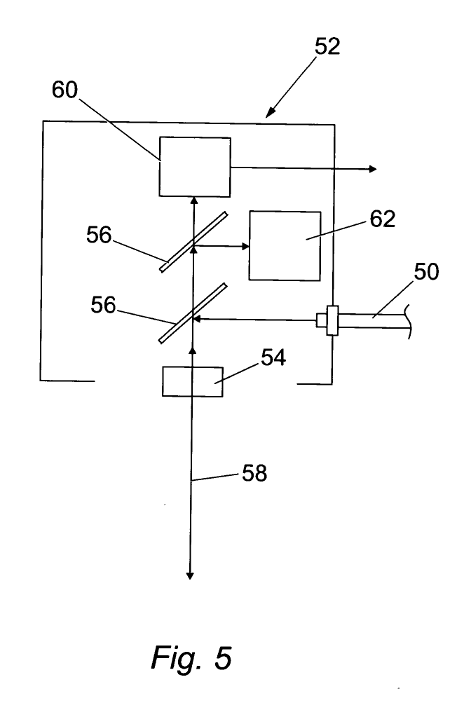

FIG. 5 shows part of the apparatus of FIG. 4 in greater details.

A typical section of the etched dielectric for the semiconductor conductor deposition scheme known as ‘Damascene’ is shown in profile in FIG. 1. Typically the structure is etched down to an etch stop layer 1 which layer provides for a slowing down of the etch so that the etch may be terminated by reference to time or alternatively the distinguishing chemical composition of the etch stop layer 1 may be determined by reference to specific wavelengths of light emitted within the plasma used to carry out the etch.

It is desirable to optimise the performance of the semiconductor device by eliminating the etch stop layer and decreasing the geometry of the device and improving the permittivity of the dielectric material, and decreasing the total number of process fabrication steps.

It is known (Ref: FR-2718231) that interferometric techniques which derive measurements from interfering optical signals (FIG. 2) reflected from the top of the etched surface 2, the top of the mask 3, the bottom of the etched film 4, and the bottom of the mask 5 can yield data throughout the etch. Furthermore, it is known (Ref: U.S. Pat. No. 6,226,086 B1) that processing the data relative to a mathematical model of the physical situation provides additional useful information so that remaining thickness and etch rate can be determined with high accuracy providing an improvement in process control and possible elimination of the need for an etch-stop layer.

An analogous situation exists where a film is being deposited rather than etched.

It is common practice to deliver the optical signal as a focussed spot in such a way that the illumination substantially falls on the surface being etched. Although common this practice has the disadvantage that the spot size is practically limited by diffraction to about 5 microns. This size is no longer compatible with the development of semiconductor, MEMs and waveguide devices, which are now below one micron in feature size.

An alternative is to illuminate a larger area: this has the advantage of illuminating a number of structures and some diffraction effects will provide a modulation of the signal, which can enable endpoint detection. However, with known techniques very little of the signal couples into the structures and the etched films and the endpoint signatures are consequentially weak and ill defined.

It is a prime objective of this invention to provide a means for efficient coupling of an interferometric probe beam into the combined structure of mask, etched film and/or substrate by using an illumination means with a wavelength or wavelengths which are deliberately chosen so that the mask and film into which the small structures are to be etched maximise their interaction with the illumination and thus continue to provide strong modulation by means of interference between the incoming and reflected waves even though the structures themselves are below the diffraction limit of the illuminating probe beam.

Proper choice of wavelength involves consideration of the structure dimension, its orientation with respect to the polarisation planes of the probe beam, and consideration of its spacing and repeat to the structures surrounding it. If mathematical analysis does not yield a suitable wavelength choice using the repetition of structures present naturally (that is, arising from the desired structure design) on the substrate, then the invention provides for a specific test structure to be placed on the substrate with a repetitive structure which can be easily analysed. Such test structures can conveniently be placed in the scribe lines conventionally present on semiconductor wafers. If a test structure is used, it is selected to have a geometry which simultaneously meets the requirements of optimising the coupling to the structure at a feature size that is fully representative of the feature size to be monitored during the thin film etch or deposition process.

This invention exploits these coupling effects to provide measurement during the etch or deposition process. The mask (if used) and substrate materials are opaque to the probe wavelength which is chosen to be close to the separation of the features as projected onto the plane normal to the incident beam; ‘close’ in this context is taken to be within 30%. Under these conditions the feature size itself can be as small as 1/10 of the illuminating probe wavelength. A cooperative effect of the illuminating radiation governed by the separation of the features being equal or close to the wavelength or wavelengths of the illuminating probe results in an interference reflection signal which is modulated by the etch depth. This effect predominantly interacts with only one of the polarisation components of the illumination, and by separating the reflected beam into its polarisation components considerable improvement in signal quality can be obtained by referencing one polarisation mode to the others. This feature can also be used to remove undesirable modulation of the detected signal by etch of the mask rather than etch of the feature which it is desired to detect.

In the case where the etched feature contains a substantially transparent film overlying a substantially opaque film or substrate material, the solution of Maxwell's equations at the surface shows that modulation of the interference signal occurs which indicates remaining thickness of the substantially transparent film. This remaining thickness is a very desirable measurement as it permits the endpoint of an etch part-way through a film as is required for dielectric etch in the case where an etch stop layer is not provided, or for the process of slowing down an etch before the critical endpoint so as not to break through a thin residual film (as in the process known as ‘soft landing’ for gate etch), or in circumstances where it is desirable to change the etch conditions before the final process endpoint in order to optimise the etch by, for example, changing the degree of sideways etch for gate width optimisation purposes.

Consider the example wafer structures shown in FIG. 2. The structures 6 that it is desired to etch have a line width of 0.2 microns.

The test structure 7 that would have previously been required has a dimension of 10 microns. This would accommodate a focussed spot diffraction limited at 5 microns from a monitoring interferometer, but the large size of the feature would mean that the etch process would proceed at a different rate in the test feature from that within the structure that requires to be manufactured. As such the monitoring technique will not return a useful measure.

Now consider the array of features shown in the test structure 8 on the example wafer. These have a feature size (0.2 um) that is representative of the size of the process feature 6 that requires to be monitored, but in addition they have a geometrical arrangement that has been carefully chosen to optimise coupling of the incident interferometric monitor beam into the region below the mask. It will be appreciated that a suitable arrangement may naturally follow from the circuit design or other design on the substrate as an alternative to optimising the effect by use of a test structure.

FIG. 3 represents a cross-section of the test structure 8. This has features 20 with a feature size (0.2 um in this example) which is representative of the size of the process feature 6 (FIG. 2) which requires to be monitored. In addition, the spacing between features 20 is chosen such that the repeat distance 22 is equal to the wavelength λ of the inspecting beam or to a multiple thereof 2λ, 3λ etc. Alternatively, as discussed above the wavelength may be chosen to be up to 30% away from the nk value.

The foregoing assumes that the inspection beam will be normal to the surface of the wafer. Where this is not the case, the distance 22 is increased such that its projection on the plane normal to the inspection beam is equal to λ, 2λ, 3λ, etc

Provided that the etched film and the mask are substantially opaque to the incident wavelength, and if the features occupy a sufficient proportion of the surface area (between 5% and 95% of the illuminated area), the incident radiation will couple with the resonant volume apparent to the illuminating radiation and yield an interferometric measure of the etch or deposition which can then be used to determine the process endpoint or to control process rate and uniformity.

One apparatus for carrying out the invention is illustrated in FIG. 4. The apparatus includes an enclosure 40 which can be evacuated via an exhaust line 42 by a vacuum pump (not shown). A support 44 locates a semiconductor wafer 46 in line with a window 47 for transmission of optical beams. It will be understood that the apparatus is provided with means for supplying etchant gas, plasma, or other processing media in conventional manner.

A light source 48 supplies monochromatic light via a fibre optic cable 50. The light source 48 may be a single frequency laser, a tuneable laser, or a wideband light source interfaced to a wavelength selector such as one or more filters.

The fibre optic cable 50 links the light output to an optical head assembly 52 shown in more detail in FIG. 5. The optical head assembly includes lenses 54 and beamsplitters 56 to cause an optical probe beam 58 to illuminate the wafer 46 at right angles to the plane of the wafer 46, and to direct the reflected light to a detector 60. A camera 62 may optionally be provided to assist the operator in directing the beam 58.

The optical head assembly may be mounted on translation stages and gimbals (not shown) in known manner, so that the beam can be adjusted in position and angle.

The detector 60 provides an electrical output signal representative of the reflected optical signal, which is passed to a signal processing means 64 to provide a process control signal 66. The signal processing means 64 may conveniently comprise analog-to-digital conversion followed by numerical processing. Suitable forms of apparatus for detecting the reflected signal and processing the detected signal are well known in the art and not described in detail herein.

As discussed above, the detector 62 has the function of comparing one polarisation in the reflected beam at right angles to the plane of the wafer with the cross polarisation. In the conditions described, there is a cooperative effect known as ‘anomalous reflection’ or ‘Rayleigh Resonance’ and the reflection for the one polarisation undergoes oscillations with the oscillation representing the depth of the etch.

The basic purpose of the signal processing is to compare the real-time performance with a model of the desired process, which model may be derived by mathematical analysis or from a trial run which is known to have produced an acceptable result.

The signal processing may, in one example, comprise applying a shape or pattern recognition algorithm to the data stream. In a preferred form, the data stream is first subjected to digital filtering using a digital filter applied to one or more time windows as the signal develops, the digital filter having first been derived from a mathematical prediction of the signal behaviour.

The apparatus may be used to measure depth of etch, remaining film thickness, rate of etch, and a figure of merit giving an average width of etch. Such measurements can be used to control the progress of the etch process; indicate the endpoint of the etch; give early warning of the endpoint approach so that the etch can be slowed down or the chemistry of the etch changed to fine-tune the process (commonly called a ‘soft landing’); or to permit the etch to be stopped part-way through a film, eliminating the requirement for an etch stop layer.

The invention thus provides a means for monitoring and determining the endpoint of the etch and deposition processes in situations where the feature size is small in relation to light beams which can be practically provided.

1. A method for improved control of etch or deposition in a semiconductor manufacturing process to produce a structure having a small feature size, the method comprising:
providing an illumination source at one or more selected wavelengths;
generating from said illumination source an optical probe measurement beam;
illuminating an article undergoing processing with said beam, the article having within the area of illumination an ordered feature arrangement having a feature size of the same order as the structure to be produced and being arranged in a regular pattern having a given feature spacing or spacings;
said selected wavelength or each of said selected wavelengths being within 30% of a whole number of wavelengths of a size equal to the projection on a plane normal to the illuminating radiation of said feature spacing or a respective one of said feature spacings;
detecting an oscillation of a polarization component in the light beam reflected from the article being processed which is derived substantially from anomalous reflection or Rayleigh Resonance at the feature arrangement resulting from the illumination; and
using the oscillation to detect or predict the desired endpoint or monitor the progress in real time of the etch or deposition.

2. The method of claim 1, in which the ordered feature arrangement is a test structure applied to the article for the purpose of monitoring the process.

3. The method of claim 1, in which the ordered feature arrangement comprises structural features of the desired article itself.

4. The method of claim 1, in which the article has an overlying mask which is substantially opaque to the wavelength of the illumination source.

5. The method of claim 1, in which the ordered feature arrangement has a ratio of feature open to etch to features masked form the etch of between 5% and 95%.

6. The method of claim 5, in which the ordered feature arrangement has a simple repeat of the etch structure.

7. The method of claim 5, in which the ordered feature arrangement has no simple repeat of the etch structure.

8. The method of claim 1, in which the probe beam has a linear transverse dimension of 5 μm or more.

9. The method of claim 1, further including comparing the oscillation information with a model of predicted behavior.

10. The method of claim 9, in which said model is created by analyzing the process critical features, which analysis takes as its input the design of the features and their arrangement with other features in the three dimensions of the overall component together with the optical properties of the materials and the illumination wavelength or wavelengths of the illumination source.

11. The method of claim 10, in which said analysis includes analysis of the behavior of the illuminating radiation together with its polarization modes and the interference resulting from the etched (or deposited) film as its thickness varies.

12. The method of claim 11, in which said analysis is used to provide an optimized endpoint approach using the illumination source illuminating an area of an article being processed.

13. The method of claim 1, including the further step of tuning the illumination means to a selected wavelength.

14. The method of claim 13, in which said selected wavelength is chosen in dependence on the material being examined and remains constant throughout the process.

15. The method of claim 13, in which said selected wavelength is tuned to a number of different wavelengths during the process, and the detected signals are compared with a family of predictions.

16. The method of claim 15, in which the family of predictions includes predictions for feature width as well as depth, and in which the results derived from tuning to different wavelengths are compared with the best fit of a family of predictions to give an estimate of the width of the etch feature.

17. The method of claim 1, in which the spectrally narrow illumination source is provided by combining a spectrally broad source with a wavelength discriminating means.

18. The method of claim 1, in which the illumination source comprises light generated by the deposition or etch process itself.

19. The method of claim 18, in which the deposition or etch process is a plasma process.

20. Apparatus for use in s semiconductor manufacturing process, the apparatus comprising,
a vacuum enclosure;
a workpiece location within the enclosure for locating a semiconductor workpiece to be processed to produce a structure having a small feature size, said semiconductor workpiece having an ordered feature arrangement having a feature size of the same order as the structure to be produced and being arranged in a regular pattern having a given feature spacing;
an illumination source producing light at one or more wavelengths each within 30% of a whole number of wavelengths of a size equal to the projection upon a plane normal to the incident illumination of said feature spacing;
optical projection means cooperating with the light source to produce an optical probe measurement beam directed to said workpiece location;
optical detection means arranged to detect an oscillation of a polarization component in the light beam reflected from the article being processed which is derived substantially from anomalous reflection or Rayleigh Resonance at the feature arrangement resulting from the illumination; and
data processing means arranged to use the oscillation to detect or predict the desired endpoint or monitor the progress in real time of the etch or deposition.

21. Apparatus according to claim 20, in which the illumination source or the detection means or both is provided with polarization means.

22. Apparatus according to claim 21, in which said polarization means is fixed.

23. Apparatus according to claim 21, in which said polarization means is rotating.

24. Apparatus according to claim 20, in which the illumination means is tunable.

25. Apparatus according to claim 24, in which the illumination source is tuned to a plurality of wavelengths during production of a given product, and the data processing means is arranged to compare the detected signals with a family of predictions at said plurality of wavelengths.
